(19) United States
(12) Patent Application Publication
(10) Pub. No.: US 2017/0053858 A1
(43) Pub. Date: Feb. 23, 2017

(54) SUBSTRATE ON SUBSTRATE PACKAGE

(71) Applicant: INTEL CORPORATION, SANTA CLARA, CA (US)

(72) Inventors: Jan Krajniak, Phoenix, AZ (US); Carl L. Deppisch, Chandler, AZ (US); Kabirkumar J. Mirpuri, Scottsdale, AZ (US); Hongjin Jiang, Chandler, AZ (US); Fay Hua, Fremont, CA (US); Yuying Wei, Chandler, AZ (US); Beverly J. Canham, Chandler, AZ (US); Jiongxin Lu, Chandler, AZ (US); Mukul P. Renavikar, Chandler, AZ (US)

(21) Appl. No.: 14/831,528

(22) Filed: Aug. 20, 2015

(51) Int. Cl. H01L 23/498; B23K 1/20; B23K 35/02; H01L 21/48; B23K 35/26; B23K 35/30; H01L 23/00; B23K 1/00; B23K 35/36

(52) U.S. Cl. CPC H01L 23/49833; B23K 1/0016; B23K 1/20; B23K 35/025; B23K 35/3613; B23K 35/262; B23K 35/3006; B23K 35/302; B23K 35/264; H01L 23/49838; H01L 24/17; H01L 24/81; H01L 24/11; H01L 21/4853; H01L 2224/13139; H01L 2224/13147; H01L 2224/13111; H01L 2224/13113; H01L 2224/13014; H01L 2224/13016; H01L 2224/16227; H01L 2224/11334; H01L 2224/8102; H01L 2224/81815; H01L 2924/20106; H01L 2924/20104; H01L 2924/20105; H01L 2924/15331; H01L 2924/1511

(57) ABSTRACT

Embodiments herein may relate to a patch on interposer (PoINT) architecture. In embodiments, the PoINT architecture may include a plurality of solder joints between a patch and an interposer. The solder joints may include a relatively high temperature solder ball and a relatively low temperature solder paste that at least partially surrounds the solder ball. Other embodiments may be described and/or claimed.

### TECHNICAL FIELD

The present disclosure relates generally to the field of packages for electronic devices, and more specifically to substrate to substrate or substrate to printed circuit board (PCB) packages.

### BACKGROUND

Substrate to substrate architectures, for example a Patch on Interposer (PoINT) architecture, may present low cost package design opportunities. As a specific example, PoINT architecture may include a patch with a substrate that is coupled with an interposer substrate via one or more solder joints. In legacy devices, the solder joints may be reinforced with an underfill material to provide strength and structural support to the joints. If the underfill material is missing, the solder joints may experience undesirable failure symptoms such as joint cracking during temperature cycling of the package.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 depicts an example package that may include a PoINT architecture, in accordance with various embodiments.

FIG. 2 depicts a cross-sectional view of a PoINT architecture, in accordance with various embodiments.

FIGS. 3, 4, 5, and 6 depict sequential views of the generation of the PoINT architecture of FIG. 2, in accordance with various embodiments.

FIG. 7 depicts an example of increased ball shear strength in PoINT packages such as those depicted in FIG. 2, in accordance with various embodiments.

FIG. 8 is an example process for making the package of FIG. 2 or 6, in accordance with various embodiments.

FIG. 9 is an example computing device that may include the package of FIG. 1, 2, or 6, in accordance with various embodiments.

### DETAILED DESCRIPTION

Embodiments herein may include a PoINT architecture that may include solder joints that includes solder balls composed of an alloy with high ductility and high tensile strength, and an epoxy-based joint reinforcing paste (JRP) with a relatively low reflow temperature. During reflow, the JRP may flow around the solder ball and cure, which may help provide structural support to the solder joint. In this manner, the PoINT architecture may have increased structural stability without requiring underfill in the interconnect layer.

Generally, the term “high-temperature” will be used in this description to refer to an alloy used in solder balls. As used herein, “high-temperature” generally refers to an alloy with a relatively high reflow temperature, and further indicates that the alloy may have relatively high ductility and tensile strengths at temperatures near that reflow temperature. Similarly, the term “low-temperature” may be used in this description to refer to the JRP. As used herein, a “low-temperature” alloy or JRP may refer to an alloy or JRP with a relatively low reflow or curing temperature.

Embodiments described herein may in some situations refer to the solder ball as “high-temperature” and the JRP as “low-temperature.” However, this description may be for the sake of example of one embodiment only, and in other embodiments the JRP may be high-temperature. Additionally or alternatively, in other embodiments the solder balls may be low-temperature.

It will be understood that the JRP discussed herein may be described as “paste” both before and after a reflow and/or cure process may be performed on the JRP and/or the package. This description may be used for the sake of consistency and clarity while discussing the element at different stages of construction of various packages. The term is not intended to be limiting to a particular stage or form of the JRP as described herein.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

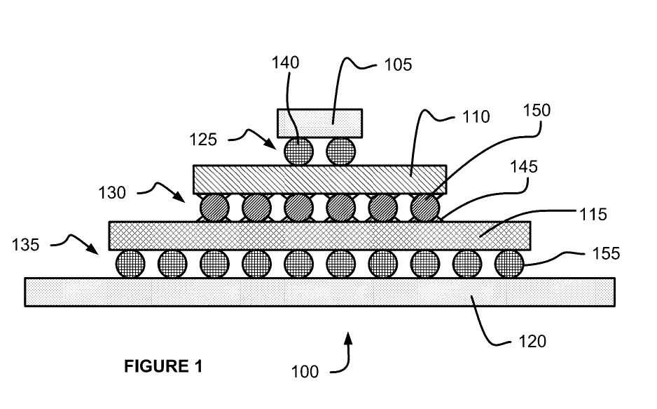

FIG. 1 depicts an example package 100 that may include a PoINT architecture. Specifically, a die 105 may be coupled with a patch 110 via one or more solder joints 125. In embodiments, the die 105 may include a central processing unit (CPU), memory, an interconnect integrated circuit (IC) and/or some other component. In embodiments, the solder joints 125 may be composed of solder balls 140 that may include an alloy of tin, silver, and copper (referred to herein as “SAC”). In embodiments, the solder joints 140 between the die 105 and the patch 110 may be collectively referred to as a first level interconnect (FLI).

Generally, in embodiments herein, the solder joints 125 may be discussed as including or being based on solder balls such as solder balls 140. In other embodiments, however, the solder joints 125 may be formed of copper bumps with a solder cap or some other configuration of solderable material.

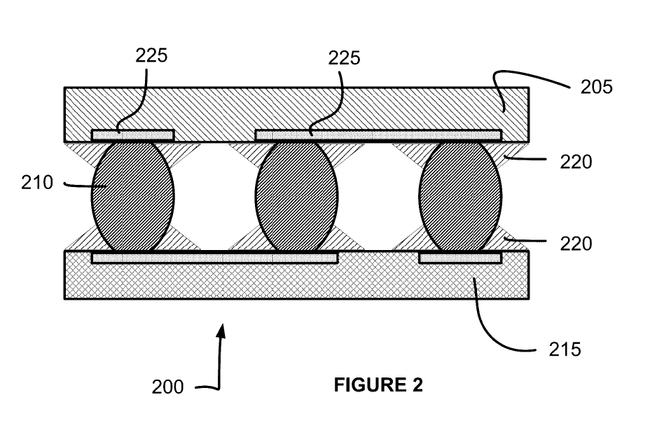

Further, the patch 110 may be coupled with the interposer 115 via a plurality of solder joints 130 that may include one or more relatively high temperature solder ball(s) 150 and a relatively low temperature JRP 145. In embodiments, the relatively high temperature solder ball(s) 150 may be composed of SAC as described above. In other embodiments, the solder balls 140 may be composed of alloys of tin and bismuth (Sn—Bi). In embodiments, the SAC and/or Sn—Bi alloys may be doped with one or more dopants such as Nickel (Ni), Manganese (Mn), Indium (In), Antimony (Sb), Strontium (Sr), Cromium (Cr), and/or Titanium/Titanium Oxide (Ti, TiO). The relatively high temperature solder ball(s) 150 and the relatively low temperature JRP 145 will be described in greater detail with reference to FIG. 2, below. As noted above, the description of relatively high temperature solder ball(s) 150 and relatively low temperature JRP 145 is intended herein as one example, and other embodiments may have relatively low temperature solder ball(s), relatively high temperature JRP, or combinations of high and low temperature JRP and/or solder balls.

In some embodiments, the solder balls 150 may be composed of a SAC alloy that is approximately 0-98% Tin, 0-5% Silver, and 0-5% Copper. The Sn—Bi solder balls may be composed of approximately 0-95% Tin and 0-58% Bismuth. Other formulations of alloy of the solder balls 140 may be discussed herein.

Generally, the solder joints 130 between the patch 110 and the interposer 115 may be collectively referred to as a middle level interconnect (MLI). The combination of the patch 110, the solder joints 130, and the interposer 115 may be generally referred to as a PoINT architecture.

Finally, the interposer 115 may be coupled with a substrate 120 such as a printed circuit board (PCB) of a computing device via solder joints 135, which may be composed of solder balls 155 arrayed in a ball grid array (BGA) as depicted in FIG. 1. The solder joints 135 may be collectively referred to as a second level interconnect (SLI) and may be composed of the same material as, or a different material than, the solder balls 140. In other embodiments (not shown), the interposer 115 may be coupled with the substrate 120 via a land grid array (LGA), a pin grid array (PGA), and/or some other type of interconnect structure.

In embodiments, the patch 110 may be considered to be relatively high density, and the interposer 115 may be considered to be relatively low density. In some embodiments, the patch 110 may be considered to be high density because the patch 110 may have a relatively high number of connections or routings (not shown) between the first side of the patch 110 that is coupled with the die 105 and the second side of the patch 110 that is coupled with the interposer 115. The connections may be relatively densely packed together due to the relatively small form factor of the patch 110, and may include one or more through silicon vias (TSVs). Similarly, the interposer 115 may be considered to be low density (or, alternatively, have an approximately similar density to legacy die packages) because it may have a similar number of connections or routings to the patch 110, but have a larger form factor 115. Therefore, the connections or routings of the interposer 115 may be less dense than those of the patch 110.

In some embodiments, “low density” may refer to having approximately 10 input/output (I/O) connections or less per millimeter (mm). “Low density” may also be referred to as having a line/space measurement of approximately 50/50 micrometers (μm). By contrast, “high density” may refer to as having approximately 20 I/O connections or more per mm. “High density” may also be referred to as having a line/space measurement of approximately 25/25 μm. In other embodiments, “low density” may refer to having a line/space measurement of greater than approximately 20/20 μm, and “high density” may refer to having a line/space measurement of less than approximately 20/20 μm. In various embodiments, the high/low density designation may refer to relative densities of the patch 110 and the interposer 115, and the specific I/O connection or line/space measurements may indicate density relative to one another.

Typically, the different densities of the patch 110 and the interposer 115 may be based on the die 105 and the substrate 120. Specifically, it may be desired for the die 105 to be communicatively coupled with a socket on the substrate 120 that may have an area that is significantly larger than that of the die. In order for the die 105 to be communicatively coupled with the socket of the substrate 120, it may be desirable for the die 105 to be coupled with one or both of the patch 110 and/or the interposer 115. However, the interposer 115 may be considered to have a relatively large form factor (i.e., lateral footprint) as compared to the die 105 and/or the patch 110, and so during the coupling process, and specifically during the reflow or curing process, the interposer 115 may warp. This warpage may be because reflow or curing generally involves the application of heat to cause the solder balls 140, 150, and/or 155 to slightly deform to physically couple the various substrates of the die 105, patch 110, interposer 115, and/or substrate 120 together. As this heat is applied, the various substrates of the die 105, patch 110, interposer 115, and/or substrate 120 may deform. The warpage may cause one or more of the solder joints 130 between the patch 110 and the interposer 115 to be closer or further than another one of the solder joints 130, which may result in an undesirable weakness such as cracking or bridging of the solder joints 130, or one of the solder balls not coupling with one of the patch 110 and/or interposer 115.

In order to reduce or eliminate the undesirable weaknesses caused by the warpage, legacy packages may have used an underfill to provide structural support for solder joints 130. However, the underfill may be undesirably expensive and/or add an additional step to the manufacturing process. By using the relatively high temperature solder balls 150 and the relatively low temperature JRP 145, the use of underfill in the MLI may not be necessary.

It will be noted that the relative sizes and number of elements in the package 100 are depicted for the purpose of example only. Specifically, the heights or lengths of the various elements such as the die 105, solder joints 125/130/125, patch 110, interposer 115, and substrate 120 may not be to scale. Additionally, the number of elements, for example the number of solder balls 140, 150, or 155 in solder joints 125, 130, and 135 may be different in different embodiments.

FIG. 2 depicts a cross-sectional view of a PoINT architecture 200. The PoINT architecture 200 may include a patch 205 and an interposer 215 which may be respectively similar to patch 110 and interposer 115. The PoINT architecture 200 may further include one or more solder balls 210, which may be similar to solder balls 150. The PoINT architecture 200 may further include JRP 220, which may be similar to JRP 145. In some embodiments, the patch 205 and/or interposer 215 may include one or more pads 225 physically and electrically coupled with one or more of the solder balls 210. In some embodiments, a pad 225 may be coupled with only one solder ball 210, while in other embodiments a pad 225 may be coupled with a plurality of solder balls 210. In some embodiments, one or more of the pads 225 may be coupled with one or more communication pathways (for example TSVs) such that a signal can pass from one side of the patch 205 and/or interposer 215 to the other, allowing communication through different layers of the PoINT architecture 200 and/or package 100.

In embodiments, the solder balls 210 may be composed of a SAC alloy with a relatively low amount of silver. For example, in some embodiments the SAC alloy may include approximately 2.3 percent by weight of silver. The SAC alloy of solder balls 210 may be doped with, for example, approximately 80 parts per million (ppm) cobalt and approximately 800 ppm nickel, and have a melting point of between approximately 221 and approximately 225 degrees Celsius. In other embodiments, the solder balls 210 may be composed of some other solder alloy with a relatively high temperature performance such as a SAC alloy with approximately 3% silver, approximately 0.5% copper, approximately 0.15% nickel, and a balance (approximately 96.35%) tin. In some embodiments, such a SAC alloy may be referred to as SAC305+0.15Ni. Other embodiments may use some other type of solder alloy that has properties similar to those of the SAC305+0.15Ni alloy or some other appropriate alloy. In embodiments, the solder balls 210 may be composed of a SAC alloy that is approximately 0-98% tin, 0-5% silver, and 0-5% copper. In other embodiments, the solder balls 210 may be composed of a Sn—Bi alloy that may be approximately 0-95% tin and 0-58% bismuth. In some embodiments, the SAC and/or Sn—Bi alloys may be doped with one or more dopants such as Nickel (Ni), Manganese (Mn), Indium (In), Antimony (Sb), Strontium (Sr), Cromium (Cr), and/or Titanium/Titanium Oxide (Ti, TiO).

Such a doped SAC alloy or Sn—Bi alloy may result in significant improvement of temperature cycle performance of solder joints that include solder balls 210. Specifically, the solder joints that include solder balls 210 may experience a significantly decreased level of cracking during temperature cycling.

Generally the presence of cobalt or some other dopant in the solder may help reduce undercooling during reflow and/or temperature cycling of the PoINT architecture 200 by providing nucleation sites. The reduced undercooling may lead to a thinner inter-metallic compound (IMC). Generally, the IMC may refer to a layer in which the atoms of the metals of the solder material are mixed with atoms of the package metal pad. An example of a IMC in the present embodiment may include (CuNi)₆Sn₅. The thinner IMC may significantly enhance temperature cycle performance of the PoINT architecture 200. Further, the presence of the nickel dopant may reduce or eliminate the formation of relatively brittle copper-tin (Cu₃Sn) crystals on the surface of the solder balls 210. It will be recognized that the above described doped SAC alloy is merely one example alloy, and other embodiments may utilize solder balls 210 composed of alternative relatively high-temperature alloys with different materials and/or dopants. In embodiments, the selection of the alloy may be based on factors such as desired reflow-temperatures of the PoINT architecture 200, compatibility with downstream processing steps, end-of-line yield, performance of the alloy in the accelerated thermal cycle reliability evaluation, and/or other factors. In some embodiments, the selection of the alloy may be based on a desire for relatively high tensile strength and/or relatively high ductility.

In embodiments, the JRP 220 may be a relatively low-temperature solder paste as described above. For example, the JRP 220 may have a reflow or melting point of approximately 160 degrees Celsius, though in other embodiments the reflow point may be higher or lower dependent on parameters of the PoINT 200 architecture and desired reflow-temperatures identified for package construction.

Although the terms “high” and “low” temperature may be applied to the JRP 220 in general, in specific embodiments the JRP 220 may include high and low melting solder powder, while the reinforcing component (i.e. the epoxy flux) may have high or low temperature curing kinetics. For example, with a JRP that includes an alloy such as Tin-Bismuth solder powder (i.e., 42 percent tin and 58 percent bismuth), the melting point of the solder powder may be approximately 140 degrees Celsius, and the cure temperature of the JRP 220 may be between approximately 160 degrees and 190 degrees Celsius. The reflow temperature of the alloy may be between approximately 130 and 200 degrees Celsius. This type of JRP may be referred to as a “low-temperature” JRP 220.

As another example, a “high-temperature” JRP may have a cure temperature between approximately 220 and 240 degrees Celsius. In some embodiments, the solder alloy of the JRP may have a relatively low melt point (e.g., 140 degrees Celsius), while in other embodiments the alloy may have a melt point of approximately 217 degrees Celsius.

In some embodiments, the solder balls 210 may likewise be considered “low-temperature” and have a reflow temperature of between approximately 130 and 200 degrees Celsius. As noted above, the solder balls 210 may in some embodiments be considered “high-temperature” and have a reflow temperature of between approximately 220 and 225 degrees Celsius.

Generally, in some embodiments, if a low temperature solder ball is used, then the JRP used on the patch may be a JRP with a high cure temperature and a solder alloy that is either high or low temperature. The JRP used on the interposer may be a JRP with a high cure temperature and a high or low temperature solder alloy or a JRP with a low cure temperature and a low temperature solder alloy.

Alternatively, if a high temperature solder ball is used, then the JRP used on the patch may be a JRP with a high cure temperature and a high or low temperature solder alloy. The JRP used on the interposer may be a JRP with a high cure temperature and a high or low temperature solder alloy or a low cure temperature and a low temperature solder alloy.

In some embodiments, the JRP 220 may be similar to a no-clean type of solder paste. Specifically the JRP 220 may, during the reflow process, leave behind an electrically inert residue that does not contribute to structural weaknesses or bridging between solder balls 210. In some embodiments, the JRP 220 may be an epoxy-based paste. In some embodiments, the JRP 220 may include an anhydrite and/or catalyst-based hardener. In some embodiments, the JRP 220 may further include or be composed of solvents, organic acids, thixotropic agents/other rheology modifiers and anti-foaming agents.

In embodiments, as will be described in detail below, during reflow the JRP 220 may at least partially melt and flow around one or more of the solder balls 210, as shown in FIG. 2. Subsequent to the reflow process, the JRP 220, and particularly the residue in JRP 220, may harden and at least partially surround one or more of the solder balls 210, providing structural support for the solder joints that includes the solder balls 210. In this manner, the structural support may come from the JRP 220, thereby negating the need for an underfill material between the patch 205 and interposer 215.

Specifically, in embodiments where the JRP 220 is an epoxy based paste, the residue in the JRP 220 may at least partially or fully cross-link during reflow, and leave components of the solder paste cured in an epoxy collar around the solder balls 210. This collar may provide reinforcement to the solder joint(s) that include the solder balls 210 against one or both of thermal and shock stress.

The protection of the JRP 220 around the solder balls 210 may play a significant role in the inhibition of crack formation during temperature cycling of the PoINT architecture 200. This inhibition may be because, during the temperature cycling, the crack initiation and propagation may occur at the interface of the solder ball 220 and pad 225 (in many cases). If that joint is surround by the protective JRP 220, for example a protective hardened epoxy, then the propensity of crack initiation and propagation may be considerably reduced due to stress reduction/dissipation provided by the JRP 220.

Although the example of FIG. 2 is described as a PoINT architecture, in other embodiments JRP 220 and solder balls 210 may be used to form a different type of substrate on PCB or substrate on substrate interconnect. For example, in some embodiments the JRP 220 and solder balls 210 may be used to form an interconnect between a die and a patch, between an interposer and a PCT or substrate, or between two other types of substrates in different packages.

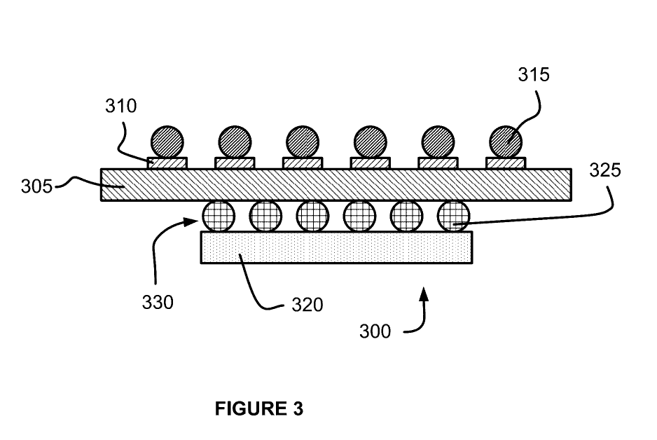

FIG. 3-6 describe steps in a sequence for generating a PoINT architecture such as PoINT architecture 200 in FIG. 2. It will be understood that in other embodiments, a similar process may be used to generate a similar architecture between a substrate and a PCB, or between another combination of a first and second substrate. In embodiments, an initial architecture 300 may include a patch 305, which may be similar to patch 110 or 205. JRP 310, which may be similar to JRP 145 or 220, may be printed on a first side of the patch 305, and one or more relatively high temperature solder balls 315, which may be similar to solder balls 150 or 210, may be positioned on the JRP 145.

In some embodiments, the initial architecture 300 may include a die 320, which may be similar to die 105. The die 320 may be coupled to the patch 305 via solder joints 330, which may be similar to solder joints 125, and include one or more solder balls 325, which may be similar to solder balls 140. Although the die 320, solder joints 330, and solder balls 325 will be depicted through the remainder of the discussion of FIGS. 3-6, in other embodiments the die 320, solder joints 330, and solder balls 325 may either be added subsequent to completion of the process of generating PoINT architecture 200, or they may not be added.

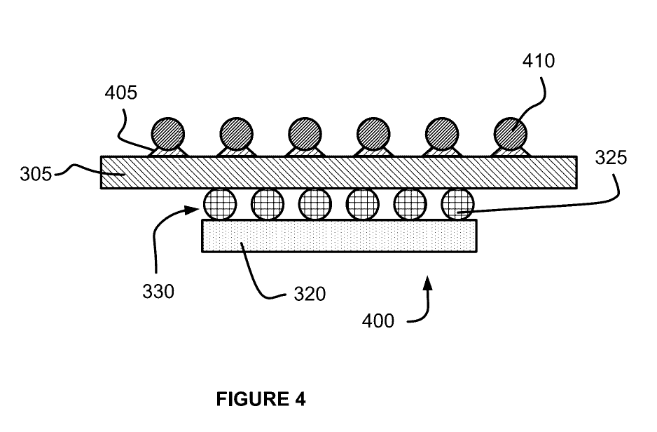

In FIG. 4, reflow may be performed on initial architecture 300 to generate architecture 400. Specifically, the reflow may include the application of heat to initial architecture 300 such as that JRP 310 at least partially deforms and flows around solder balls 315. As a result, the architecture 400 may include solder balls 410, which may be similar to solder balls 315 or which may be at least partially deformed by the reflow process, which are at least partially surrounded by the JRP 405, which may be similar to JRP 310, 145, or 220. In some embodiments, the reflow process may be performed at a temperature of approximately 240-260 degrees Celsius.

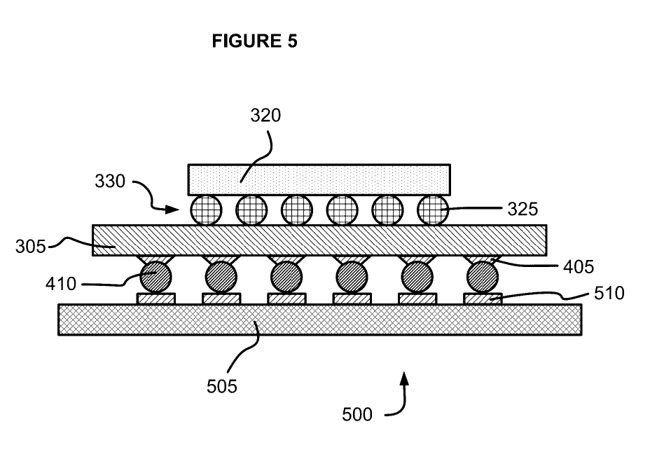

In FIG. 5, JRP paste 510, which may be similar to JRP paste 310, 145, or 220, may be printed or otherwise applied to an interposer 505, which may be similar to interposer 115 or 215. The architecture 400 may be inverted, and the solder balls 410 may be positioned on JRP 510 to form architecture 500.

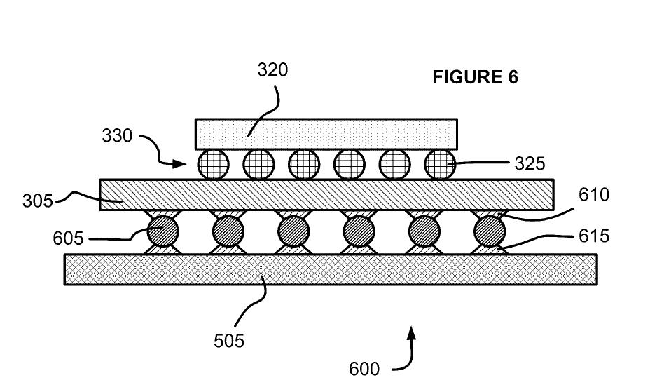

Next, as shown in FIG. 6, reflow may be performed on architecture 500 to generate architecture 600, which may include a PoINT architecture similar to PoINT architecture 200. Specifically, as described above, the reflow may include the application of heat to architecture 400 such that the JRP 510 at least partially deforms and flows around solder balls 410. As a result, the architecture 600 may include solder balls 605, which may be similar to solder balls 410 or which may be at least partially deformed by the reflow process. The solder balls 605 may be at least partially surrounded by JRP 615, which may be similar to JRP 510, 220, or 145. In some embodiments, JRP 405 may further deform during the second reflow process, thereby generating JRP 610. In other embodiments, JRP 610 may be identical to JRP 405. In embodiments, the reflow process may be performed at a temperature of approximately 160-185 degrees Celsius. In other embodiments, the reflow temperature may be higher or lower dependent on the particular architecture or package being used. For example, the temperature may change based on the composition of the various boards, the solder ball material, the JRP material, or other materials. In embodiments, the reflow temperature may be as high as 240 degrees Celsius.

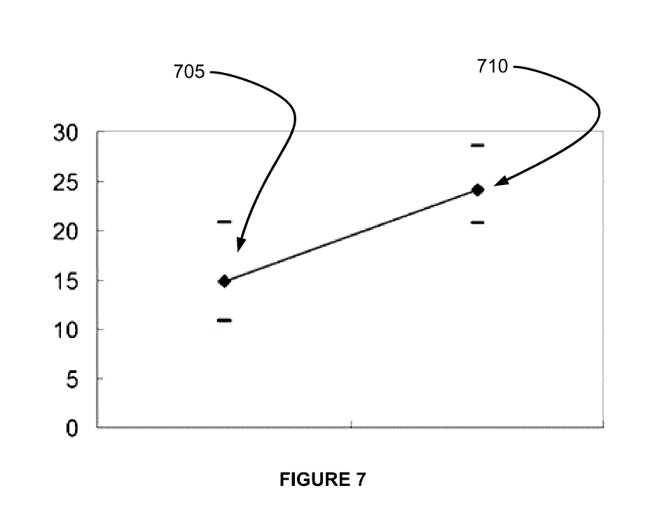

FIG. 7 depicts an example of shear strength for solder balls in a PoINT architecture such as that depicted in FIG. 2. The y axis may be a measure of shear strength in Newtons (N). Point 705 may show, with a margin of error, a shear strength for a solder ball in a solder joint that uses a legacy rosin-type solder paste. Point 710 may show, with a margin of error, a shear strength for a solder ball in a solder joint that uses JRP such as JRP 145, 220, 610, or 615. As can be seen, the shear strength for the solder joint indicated by point 710 is significantly higher than that for the solder joint indicated by point 705.

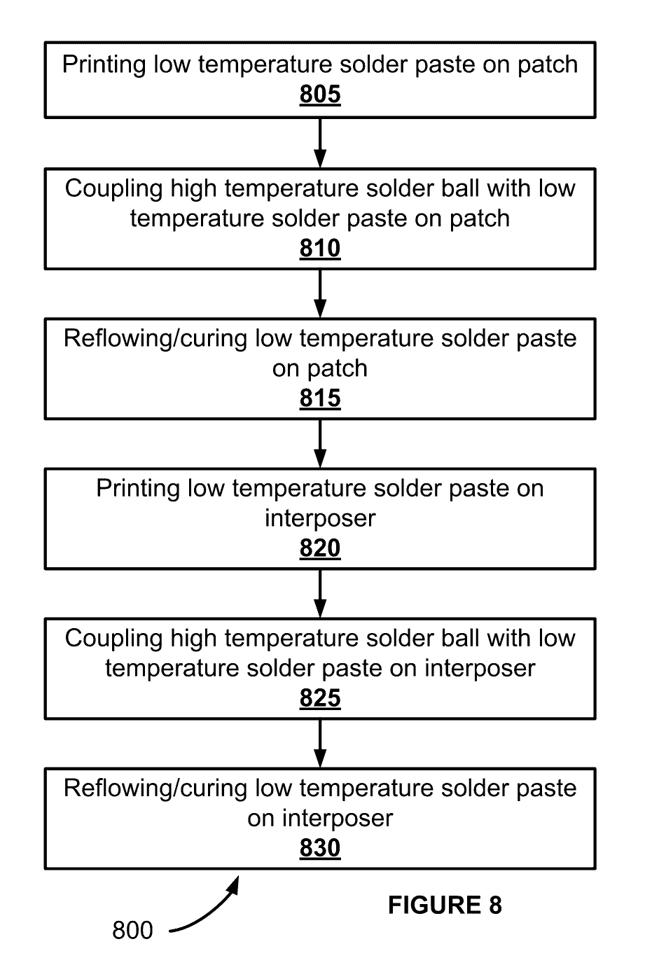

FIG. 8 depicts an example process 800 to construct a PoINT architecture such as that depicted in FIG. 2. Elements of FIG. 8 may be similar to those described above with reference to FIGS. 3-6.

Initially, a low temperature solder paste such as JRP 310 may be printed or otherwise applied to a patch such as patch 305 at 805. Next, one or more relatively high temperature solder balls such as solder balls 315 may be coupled with the low temperature solder paste on the patch at 810, and cure and/or reflow may be performed on the low temperature solder paste at 815, as described above with respect to FIG. 4.

Next, a low temperature solder paste such as low temperature solder paste 510 may be printed or otherwise applied to an interposer such as interposer 505 at 820. The high temperature solder balls such as solder balls 410 may be coupled with the low temperature solder paste at 825, and the low temperature solder paste may be cured and/or reflowed at 830 as described above with respect to FIG. 6.

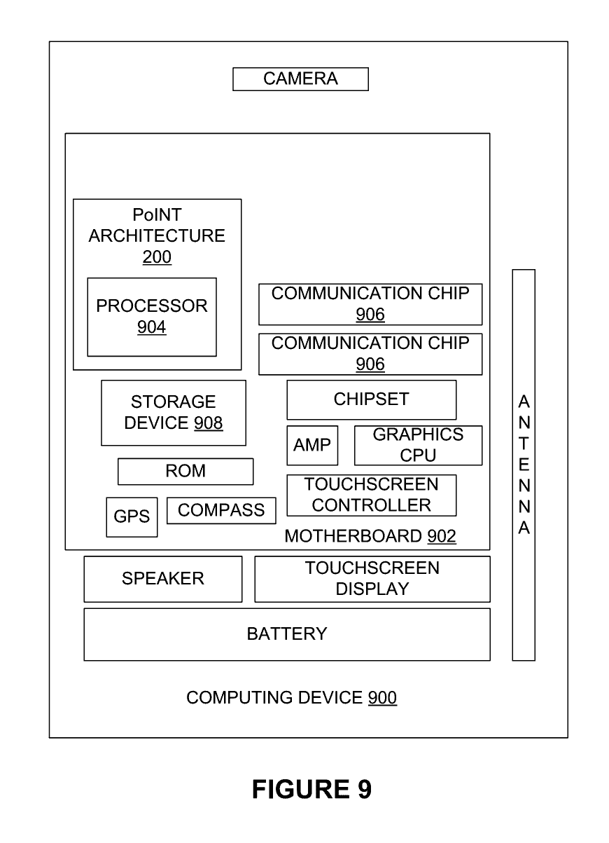

Embodiments of the present disclosure may be implemented into a system using any patches, interposers, die, substrates, and/or packages that may benefit from a simplified manufacturing process with increased structural strength as described herein. FIG. 9 schematically illustrates a computing device 900, in accordance with some implementations, which may include one or more PoINT architectures such as PoINT architecture 200.

The computing device 900 may be, for example, a mobile communication device or a desktop or rack-based computing device. The computing device 900 may house a board such as a motherboard 902. In embodiments, the motherboard 902 may be similar to substrate 120. The motherboard 902 may include a number of components, including (but not limited to) a processor 904 and at least one communication chip 906. In further implementations, the communication chip 906 may be part of the processor 904. In some embodiments, one or more of the components such as the processor 904 may be coupled with a PoINT architecture 200, which may in turn be coupled with the motherboard 902. That is, in some embodiments the processor 904 may be similar to the die 105. In other embodiments, the communication chip 906 or some other element of the computing device 900 may additionally or alternatively be coupled with the PoINT architecture 200.

The computing device 900 may include a storage device 908. In some embodiments, the storage device 908 may include one or more solid state drives. Examples of storage devices that may be included in the storage device 908 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 900 may include other components that may or may not be physically and electrically coupled to the motherboard 902. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 906 and the antenna may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 906 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 906 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 906 may operate in accordance with other wireless protocols in other embodiments.

The computing device 900 may include a plurality of communication chips 906. For instance, a first communication chip 906 may be dedicated to shorter range wireless communications such as Wi-Fi and Bluetooth, and a second communication chip 906 may be dedicated to longer range wireless communications such as GPS, EDGE, GPRS, CDMA, WiMAX, LTE, EV-DO, and others. In some embodiments, the communication chip 906 may support wired communications. For example, the computing device 900 may include one or more wired servers.

The processor 904 and/or the communication chip 906 of the computing device 900 may be or include one or more dies or other components in an IC package. Such an IC package may be directly or indirectly coupled with a patch, an interposer and/or a motherboard 902 another package using any of the techniques disclosed herein. The term “processor” may refer to any device or portion of a device that processes electronic data from registers and/or memory to transform that electronic data into other electronic data that may be stored in registers and/or memory.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data. In some embodiments, the recessed conductive contacts disclosed herein may be implemented in a high-performance computing device.

The following paragraphs provide examples of various ones of the embodiments disclosed herein.

Example 1 may include a package comprising: a first substrate with a first side and a second side opposite the first side; an second substrate with a first side and a second side opposite the first side, wherein the first and second sides of the first substrate are approximately parallel with the first and second sides of the second substrate and the first substrate and second substrate define a space between the first side of the first substrate and the first side of the second substrate; at least one solder ball disposed within the space and physically coupled with the first side of the first substrate and the first side of the second substrate; and a solder paste positioned with the space and physically coupled with the at least one solder ball, the first side of the first substrate, and the first side of the second substrate, wherein the solder paste at least partially surrounds the solder ball and the space is substantially free of an underfill material.

Example 2 may include the package of example 1, wherein the first substrate is a patch and the second substrate is an interposer.

Example 3 may include the package of example 1, wherein the solder ball includes tin, silver and copper or tin and bismuth.

Example 4 may include the package of example 1, wherein the solder paste includes epoxy.

Example 5 may include the package of any of examples 1-4, wherein the first substrate is a high density substrate.

Example 6 may include the package of any of examples 1-4, wherein the second substrate is a low density substrate.

Example 7 may include the package of any of examples 1-4, wherein the first substrate includes a die coupled with the second side of the first substrate.

Example 8 may include a method comprising: placing a solder paste on a first side of a first substrate that includes the first side and a second side opposite the first side; coupling a solder ball with the solder paste and reflowing and curing the solder paste on the first side of the first substrate such that the solder paste on the first side of the first substrate at least partially surrounds and structurally supports the solder ball; placing the solder paste on a first side of a second substrate that includes a first side and a second side opposite the first side; coupling the solder ball with the solder paste on the first side of the second substrate; and reflowing and curing the solder paste on the first side of the second substrate such that the solder paste on the first side of the second substrate at least partially surrounds and structurally supports the high temperature solder ball.

Example 9 may include the method of example 8, wherein the reflow and cure of the solder paste is at a temperature above a reflow temperature of the low temperature solder paste and above or below a reflow temperature of the high temperature solder ball.

Example 10 may include the method of example 9, wherein the solder ball has a reflow temperature between approximately 200 degrees Celsius and approximately 225 degrees Celsius.

Example 11 may include the method of example 9, wherein the solder paste has an alloy with a reflow temperature between approximately 130 degrees Celsius and approximately 200 degrees Celsius.

Example 12 may include the method of any of of examples 8-11, wherein the solder ball includes tin, silver and copper or tin and bismuth.

Example 13 may include the method of any of examples 8-11, wherein the solder paste includes epoxy.

Example 14 may include the method of any of examples 8-11, wherein the first substrate includes a high density substrate.

Example 15 may include the method of any of examples 8-11, wherein the second substrate includes a low density substrate.

Example 16 may include the method of any of examples 8-11, wherein the first substrate is a patch and the second substrate is an interposer.

Example 17 may include a package comprising: a die coupled with a first side of a patch that includes a high density substrate; a substrate coupled with a first side of an interposer that includes a low density substrate; at least one high temperature solder ball disposed between and physically coupled with a second side of the patch that is opposite the first side of the patch and a second side of the interposer that is opposite the first side of the interposer; and a low temperature solder paste disposed between and physically coupled with the at least one high temperature solder ball, the second side of the patch, and the second side of the interposer.

Example 18 may include the package of example 17, wherein the area between the second side of the patch and the second side of the interposer is substantially free of an underfill material.

Example 19 may include the package of examples 17 or 18, wherein the high temperature solder ball includes tin, silver and copper or tin and bismuth and has a reflow temperature between approximately 200 degrees Celsius and approximately 225 degrees Celsius.

Example 20 may include the package of examples 17 or 18, wherein the low temperature solder paste includes epoxy and has a cure temperature between approximately 160 degrees Celsius and 190 degrees Celsius.

Example 21 may include the package of any of examples 1-4, wherein the solder ball is a low temperature solder ball, and wherein the solder paste has a high cure temperature, and wherein the solder paste includes a solder alloy with a high reflow temperature or a low reflow temperature.

Example 22 may include the package of any of examples 1-4, wherein the solder ball is a low temperature solder ball, and wherein the solder paste has a low cure temperature, and wherein the solder paste includes a solder alloy with a low reflow temperature.

Example 23 may include the package of any of examples 1-4, wherein the solder ball is a high temperature solder ball, and wherein the solder paste has a high cure temperature, and wherein the solder paste includes a solder alloy with a high reflow temperature or a low reflow temperature.

Example 24 may include the package of any of examples 1-4, wherein the solder ball is a high temperature solder ball, and wherein the solder paste has a low cure temperature, and wherein the solder paste includes a solder alloy with a low reflow temperature.

1. A package comprising:
a first substrate with a first side and a second side opposite the first side;
a second substrate with a first side and a second side opposite the first side, wherein the first substrate and second substrate define a space between the first side of the first substrate and the first side of the second substrate;
a solder ball disposed within the space and physically coupled with the first side of the first substrate and the first side of the second substrate; and
a solder paste positioned within the space and physically coupled with the solder ball, the first side of the first substrate, and the first side of the second substrate, wherein the solder paste partially surrounds the solder ball while the solder ball is partially exposed.

2. (canceled)

3. The package of claim 1, wherein the solder ball includes an alloy of tin, silver and copper, or an alloy of tin and bismuth.

4. The package of claim 1, wherein the solder paste includes epoxy.

5. The package of claim 1, wherein the first substrate has approximately 20 inptut/output connections or more per millimeter, or has a line/space measurement of less than approximately 20/20 micrometers.

6. The package of claim 1, wherein the second substrate has approximately 10 input/output connections or less per millimeter, or has a line/space measurement of greater than approximately 20/20 micrometers.

7. The package of claim 1, wherein the first substrate includes a die coupled with the second side of the first substrate by a solder joint without being in contact with the solder paste.

8. A method comprising:
placing a solder paste on a first side of a first substrate that includes the first side and a second side opposite the first side;
coupling a solder ball with the solder paste and reflowing and curing the solder paste on the first side of the first substrate such that the solder paste on the first side of the first substrate at least partially surrounds and structurally supports the solder ball;
placing the solder paste on a first side of a second substrate that includes a first side and a second side opposite the first side;
coupling the solder ball with the solder paste on the first side of the second substrate; and
reflowing and curing the solder paste on the first side of the second substrate such that the solder paste on the first side of the second substrate at least partially surrounds and structurally supports the high temperature solder ball.

9. The method of claim 8, wherein the reflow and cure of the solder paste is at a temperature above a reflow temperature of the low temperature solder paste and above or below a reflow temperature of the high temperature solder ball.

10. The method of claim 9, wherein the solder ball has a reflow temperature between approximately 200 degrees Celsius and approximately 225 degrees Celsius.

11. The method of claim 9, wherein the solder paste has an alloy with a reflow temperature between approximately 130 degrees Celsius and approximately 200 degrees Celsius.

12. The method of claim 8, wherein the solder ball includes tin, silver and copper or tin and bismuth.

13. The method of claim 8, wherein the solder paste includes epoxy.

14. The method of claim 8, wherein the first substrate includes a high density substrate.

15. The method of claim 8, wherein the second substrate includes a low density substrate.

16. The method of claim 8, wherein the first substrate is a patch and the second substrate is an interposer.

17. A package comprising:
a die coupled with a first side of a patch by a solder joint,
an interposer with a first side and a second side;
a solder ball disposed between and physically coupled with a second side of the patch that is opposite the first side of the patch and the second side of the interposer that is opposite the first side of the interposer; and
a solder paste disposed between and physically coupled with the solder ball, the second side of the patch, and the second side of the interposer, wherein the solder paste partially surrounds the solder ball while the solder ball is partially exposed, and the solder joint is not in contact with the solder paste.

18. (canceled)

19. The package of claim 17, wherein the solder ball includes an alloy of tin, silver and copper, or an alloy of tin and bismuth, and has a reflow temperature between approximately 200 degrees Celsius and approximately 225 degrees Celsius.

20. The package of claim 17, wherein the solder paste includes epoxy and has a cure temperature between approximately 160 degrees Celsius and 190 degrees Celsius.
